(19) United States
(12) Patent Application Publication
(10) Pub. No.: US 2026/0166650 A1
(43) Pub. Date: Jun. 18, 2026

(54) METHOD AND SYSTEM FOR ADJUSTING GROOVE PROFILE FOR LASER GROOVING

(71) Applicant: Zhejiang Darcet Technology Co, Ltd, Huzhou (CN)

(72) Inventors: JANE JIAYING SOH, Huzhou (CN); Baishun GUO, Huzhou (CN)

(73) Assignee: Zhejiang Darcet Technology Co, Ltd, Huzhou (CN)

(21) Appl. No.: 19/299,925

(22) Filed: Aug. 14, 2025

(30) Foreign Application Priority Data
Aug. 16, 2024 (CN) 202411127965.7

(51) Int. Cl. B23K 26/073; B23K 26/03; B23K 26/064; B23K 101/40; G06T 7/00; G06T 7/13; H10P 34/42; H10P 74/20

(52) U.S. Cl. CPC B23K 26/0736; B23K 26/032; B23K 26/0643; B23K 26/0648; G06T 7/0004; G06T 7/13; H10P 34/42; H10P 74/203; B23K 2101/40; G06T 2207/20084; G06T 2207/30148

(57) ABSTRACT

The present disclosure relates to a method and system for adjusting a groove profile for laser grooving, aiming to improve the precision and efficiency of a laser grooving process, and is particularly suitable for the field of semiconductor manufacturing. According to the method, through steps of wafer identification, feature extraction, groove profile feature input, laser parameter setting, spot adjustment, grooving, and inspection, automated and intelligent adjustment of the laser grooving process is achieved, and the grooving quality and production efficiency are improved. By introducing advanced technologies such as a particle swarm optimization (PSO) algorithm and a convolutional neural network (CNN), the present disclosure not only can automatically optimize laser parameters to ensure high quality and consistency of a groove profile, but also can achieve precise adjustment of a spot and real-time detection and evaluation of the groove profile, thereby comprehensively improving the overall level of the laser grooving process.

### CROSS-REFERENCE TO RELATED APPLICATIONS

This application claims priority to Chinese Application No. 202411127965.7, filed on Aug. 16, 2024, entitled “METHOD AND SYSTEM FOR ADJUSTING GROOVE PROFILE FOR LASER GROOVING”, which is specifically and entirely incorporated by reference.

### FIELD OF THE INVENTION

The present disclosure relates to the field of wafer processing, in particular to a method and system for adjusting a groove profile for laser grooving.

### BACKGROUND OF THE INVENTION

In the semiconductor manufacturing industry, as the dimension of wafers continues to increase and process requirements become increasingly precise, a grooving process has become increasingly important. The grooving process not only affects the mechanical stability of wafers, but also has a direct impact on subsequent chip processing and packaging processes. Traditional mechanical grooving methods, due to contact-based processing, can cause micro-cracks and damage to surfaces of the wafers, making it difficult to meet the processing requirements for high precision and high quality. Laser grooving, as a non-contact processing technology, has gradually become the mainstream technology for wafer grooving due to its advantages of high precision, high efficiency, high flexibility, etc. However, the quality and consistency of groove profiles during laser grooving directly affect the final quality of the wafers. Therefore, an effective method for adjusting a groove profile for laser grooving is needed to optimize laser parameters and ensure high-quality groove profiles.

Patent No. KR20150047009A discloses a laser grooving apparatus and method. According to the laser grooving method, laser beams are provided by a laser source unit, and are converted into rod-shaped laser beams with a uniform intensity through a phase mask, and the rod-shaped laser beams are focused onto an object to be processed through a focusing lens. The size of the laser beams is adjusted by using an aperture adjuster, and the laser beams are moved during processing. Finally, a groove with a controllable width and a flat bottom is formed in the object to be processed. However, the method still has certain limitations in practical applications, including:
1. Low intelligence: the method mainly relies on a fixed phase mask and aperture adjuster for spot adjustment, and lacks intelligent and automated adjustment mechanisms. Dynamic adjustments cannot be achieved on the basis of spot changes during processing.
2. Low flexibility: adjustment ranges of the phase mask and the aperture adjuster are limited, making the method difficult to meet various complex processing requirements. Manual or semi-automatic adjustment methods are low in adjustment velocity and inefficient when dealing with different processing requirements. It is difficult for the method to deal with complex and variable processing requirements.

Therefore, it is particularly necessary to develop a new method for adjusting a groove profile for laser grooving.

### SUMMARY OF THE INVENTION

### (1) Technical Problems Solved

To address the defects in the prior art, the present disclosure aims to provide a method and system for adjusting a groove profile for laser grooving in order to solve the problems in the prior art. Specifically, the present disclosure aims to provide a method for adjusting a groove profile for laser grooving based on intelligent algorithms and image processing technologies. Through steps of wafer identification, feature extraction, groove profile feature input, laser parameter setting, spot adjustment, grooving, and inspection, automated and intelligent adjustment of the laser grooving process is achieved, and the grooving quality and production efficiency are improved. By introducing advanced technologies such as a particle swarm optimization (PSO) algorithm and a convolutional neural network (CNN), the present disclosure not only can automatically optimize laser parameters to ensure high quality and consistency of a groove profile, but also can achieve precise adjustment of a spot and real-time detection and evaluation of the groove profile, thereby comprehensively improving the overall level of the laser grooving process.

### (2) Technical Solutions

To achieve the above objective, the present disclosure provides the following technical solutions.

A method for adjusting a groove profile for laser grooving, including:
a wafer identification step: controlling, by a central processing unit, a scanning device to acquire color wafer images, converting the acquired color wafer images into grayscale images, identifying an edge of a wafer by using an edge detection algorithm Canny, and identifying a shape and dimensions of the wafer;
a feature extraction step: extracting, by the central processing unit, shape features, geometric features, and edge features of the wafer, including edge smoothness S, edge continuity C, and histogram of oriented gradient (HOG) uniformity U of the wafer, and constructing a comprehensive feature vector Q by fusing the extracted wafer features;
a groove profile feature input step: determining, based on a feature extraction result of the wafer and specific application requirements, specifications of a groove profile required to be designed, and inputting groove profile features into the central processing unit;
a laser parameter setting step: defining, by the central processing unit based on the extracted wafer features, an objective function for evaluating grooving effects under different laser parameters, optimizing the laser parameters by using a particle swarm optimization (PSO) algorithm, and outputting the optimized laser parameters;
a spot adjustment step: controlling, by the central processing unit, the scanning device to capture a current image of a laser spot and preprocessing the image, extracting edges, basic shape features and energy distribution features of the spot by using the algorithm Canny, and inputting the spot image into a convolutional neural network (CNN) model to generate specific spot adjustment parameters; and
a grooving and inspection step: outputting, to a laser device by the central processing unit, the optimized laser parameters and the generated spot adjustment parameters, including laser power, a scanning velocity, and a focal length, performing a grooving operation, acquiring a groove profile image upon completion of grooving, performing contour detection and geometric property calculation on the groove profile based on the groove profile image, analyzing groove profile quality, and performing result evaluation and feedback.

In the wafer identification step, the steps of the edge detection algorithm Canny include:
1. Gaussian filtering: performing Gaussian filtering on the image to reduce noise in the image and retain edge information of the image;
2. gradient calculation: performing a convolution operation on the image by using a Sobel operator, calculating a horizontal gradient Gx and a vertical gradient Gy of the image, and calculating a gradient intensity G and a gradient direction θ of each pixel;
3. non-maximum suppression: traversing each pixel in the image and checking two neighboring pixels of the pixel in the gradient direction, comparing the gradient intensity of a current pixel with the gradient intensities of the two neighboring pixels, in a case where the gradient intensity of the current pixel is not the maximum, setting the gradient intensity of the current pixel to 0, and obtaining an image containing true edge points upon traversing the pixels;
4. dual-threshold processing: setting a high threshold and a low threshold, and in a case where the gradient intensity of a pixel is higher than the high threshold, considering the pixel as a true edge; in a case where the gradient intensity of a pixel is lower than the low threshold, not considering the pixel as an edge; and in a case where the gradient intensity of a pixel falls between the two thresholds, checking neighboring pixels of the pixel, in a case where any neighboring pixel is a true edge, considering the corresponding pixel as a potential edge, otherwise, not considering the corresponding pixel as an edge; and
5. edge connection: connecting all potential edges to form a complete edge.

Preferably, in the feature extraction step, a step of calculating the HOG uniformity U includes: counting, based on the horizontal gradient Gx and the vertical gradient Gy of each pixel obtained in the wafer identification step, gradient directions of all pixels to generate a histogram of oriented gradient (HOG), wherein a calculation formula of the HOG uniformity U is:

$$U = - {\sum }_{i = 1}^{N} p ( i ) log ( p ( i ) ) .$$

Preferably, in the feature extraction step, a calculation formula of the comprehensive feature vector Q is:

$$Q = ω1 \times S + ω2 \times C + ω3 \times U .$$

Preferably, in the groove profile feature input step, the groove profile features include: a grooving depth D, a grooving width W, and a shape and dimensions of a groove profile.

Preferably, in the laser parameter setting step, the step of optimizing the laser parameters by using the particle swarm optimization (PSO) algorithm includes:
1. PSO algorithm initialization: initializing a particle swarm and randomly generating positions and velocities of particles;
2. fitness evaluation: calculating a fitness value of each particle and evaluating a grooving effect through the objective function;
3. personal best position pBest and global best position gBest update: updating a personal best position of a particle in a case where a current fitness value is superior to a historical best value; and updating the global best position in a case where the current fitness value is superior to a global best value;
4. velocity and position update: updating the velocities and the positions of the particles to ensure that the velocities and the positions are within a parameter range;
5. an iteration process: repeatedly performing fitness evaluation, pBest and gBest update, and velocity and position update until fitness convergence is achieved; and
6. output of optimal parameters: outputting a laser parameter set corresponding to the global best position as the optimal parameters.

Preferably, in the spot adjustment step, the basic shape features of the spot include an area, a shape factor, and a center position, and the energy distribution features of the spot include a center intensity and an average intensity within a radius.

Preferably, in the spot adjustment step, a training process of the CNN model includes:
1. dataset preparation: collecting a large number of sample images containing various spot patterns and corresponding adjustment parameters and corresponding adjustment strategies of the sample images, including power, a focal length, and a scanning velocity of the spot;
2. data preprocessing: standardizing the images in a dataset and partitioning the dataset;
3. CNN model design: designing the CNN model, wherein the model includes a convolutional layer, a pooling layer, and a fully connected layer, and defining an activation function and an output layer structure;
4. model training: training the model by using a training set, and updating model parameters through forward propagation and backward propagation;
5. hyperparameter adjustment: adjusting hyperparameters during training, including a learning rate, a batch size, and hyperparameters of an optimizer; and
6. model testing: evaluating the performance of the model using a test set, including a generalization capability and prediction accuracy of the model, and evaluating the performance of the model based on evaluation metrics, wherein the evaluation metrics include a mean squared error (MSE), a mean absolute error (MAE), and an R² coefficient of determination.

An adjustment system for a method for adjusting a groove profile for laser grooving includes:
1. a high-resolution scanning device for scanning wafer images and acquiring high-resolution image data;
2. a central processing unit for monitoring, analyzing, and processing the acquired image data;
3. a laser device for an actual wafer grooving operation; and
4. a user interface device for providing a human-computer interaction interface for users to set parameters, monitor processes, and check results.

Preferably, the laser device includes: a laser unit, and a light-emitting end of the laser unit is provided with a first reflector; a reflective end of the first reflector is provided with a beam expander, and the beam expander is used for adjusting a size of a spot; a light-emitting end of the beam expander is provided with a second reflector; a reflective end of the second reflector is provided with a half wave plate, and the half wave plate is used for changing a laser polarization direction; a light-emitting end of the half wave plate is provided with a spatial light modulator, and the spatial light modulator is used for adjusting a shape and energy distribution of the spot; a light-emitting end of the spatial light modulator is provided with an 4F system, and the 4F system includes two convex lenses for imaging the spatial light modulator and filtering out impurities in laser beams; and a light-emitting end of the 4F system is provided with a third reflector, a reflective end of the third reflector is provided with an objective lens, and the objective lens is used for focusing laser beams on a product surface to achieve laser grooving in the product surface.

### (3) Beneficial Effects

The present disclosure aims to provide a method and system for adjusting a groove profile for laser grooving, which have significant beneficial effects. First, by introducing advanced image processing technologies such as Canny edge detection and HOG feature extraction, the shape, geometric features, and edge features of the wafer are effectively identified and extracted, so that precise wafer identification and feature extraction are ensured. Second, combined with specific application requirements, the wafer features are input into the groove profile specifications, so that the accuracy of the designed groove profile is ensured. By optimizing the laser parameters using the particle swarm optimization (PSO) algorithm, the efficiency and accuracy of grooving parameter setting are significantly improved. By controlling the capture and processing of the spot image, and in combination with the convolutional neural network (CNN), precise spot adjustment parameters are generated, so that optimization of the shape and energy distribution of the spot is ensured. Finally, by acquiring the image of the groove profile upon grooving, and performing contour detection and geometric property calculation, the groove profile quality can be comprehensively evaluated and fed back. Due to the automation and intelligence of the method, the grooving quality and production efficiency are significantly improved, manual intervention and trial-and-error costs are reduced, and the method is particularly suitable for semiconductor manufacturing processes requiring high precision and high quality. Through synergistic optimization of a series of steps, the method provides a comprehensive and systematic solution for the laser grooving process.

### BRIEF DESCRIPTION OF DRAWINGS

By reading the detailed description of the preferred implementations below, various other advantages and benefits will become apparent to a person of ordinary skill in the art. The drawings are provided merely for the purpose of illustrating the preferred implementations and are not intended to limit the present disclosure. Throughout the drawings, the same reference numerals are used to denote the same components. In the figures:

FIG. 1 is a schematic diagram of a laser device according to an embodiment of the present application.

FIG. 2 is an implementation flowchart of a method and system for adjusting a groove profile for laser grooving according to an embodiment of the present application.

FIG. 3 is a flowchart of a wafer identification step in a method and system for adjusting a groove profile for laser grooving according to an embodiment of the present application.

FIG. 4 is a flowchart of a laser parameter setting step in a method and system for adjusting a groove profile for laser grooving according to an embodiment of the present application.

FIG. 5 is a flowchart of a spot adjustment step in a method and system for adjusting a groove profile for laser grooving according to an embodiment of the present application.

FIG. 6 is a schematic diagram of input groove profile features and output spot parameters in Application Example 1 of the present application.

FIG. 7 is a schematic diagram of input groove profile features and output spot parameters in Application Example 2 of the present application.

FIG. 8 is a schematic diagram of input groove profile features and output spot parameters in Application Example 3 of the present application.

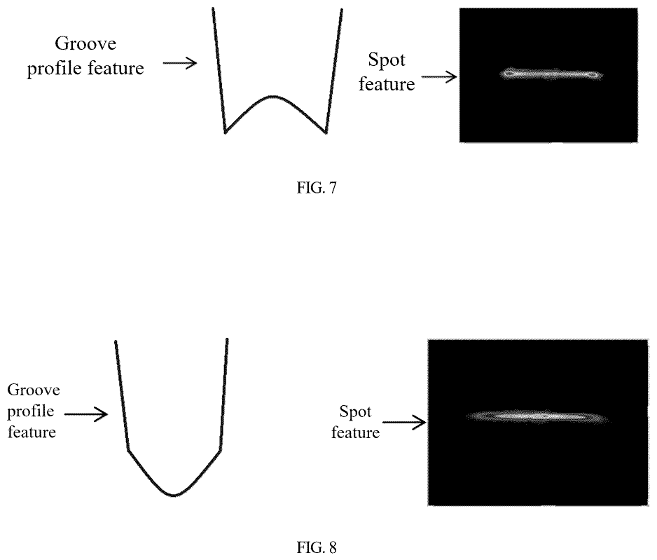

Please note that FIG. 6, FIG. 7 and FIG. 8 display different energy distributions using colors.

### DETAILED DESCRIPTION OF THE EMBODIMENTS

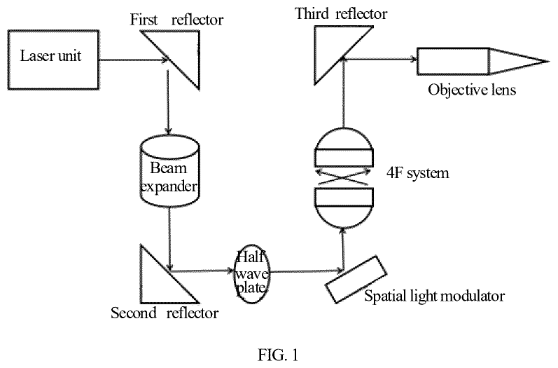

The technical solutions in the embodiments of the present disclosure will be described clearly and completely below in conjunction with FIG. 1 to FIG. 8 in the embodiments of the present disclosure. Apparently, the described embodiments are merely part of the embodiments of the present disclosure, rather than all embodiments, and based on the embodiments in the present disclosure, all other embodiments obtained by a person of ordinary skill in the art without making creative labor belong to the scope of protection of the present disclosure.

An embodiment of the present application provides a method for adjusting a groove profile for laser grooving. The method includes the following steps I to VI.

### I. Wafer Identification

1. Image Acquisition: a central processing unit (CPU) controls a high-resolution scanning device to perform scanning to acquire wafer images to be processed.
2. Grayscale conversion: the central processing unit converts the acquired color images into grayscale images. This step may be achieved using a formula Gray=Rx 0.299+Gx 0.587+B×0.114, where R, G, and B represent red, green, and blue channels of an original image, respectively.
3. Edge detection: the central processing unit identifies an edge of a wafer by using an edge detection algorithm. An algorithm Canny is used to calculate pixel intensity changes in the images so as to detect edges. In the algorithm Canny, first, a Gaussian filter is used to remove noise of an image, then a gradient intensity and a gradient direction of the image are calculated to find potential edges, and finally dual-threshold processing and edge connection are performed to obtain a true edge. The operation specifically includes the following steps:

Gaussian filtering: Gaussian filtering is performed on the image to reduce noise in the image. A linear smoothing filter is adopted for Gaussian filtering, and may retain edge information of the image while eliminating high-frequency noise. In this step, a Gaussian filter (also known as a Gaussian kernel) may be used for convolving with the image to obtain a smoothed image.

Gradient calculation: upon Gaussian filtering, the gradient intensity and the gradient direction of the image are calculated to find potential edges. The operation specifically includes:
a. Calculation of horizontal and vertical gradients: which is achieved through convolution operations. A specific convolution kernel (a Sobel operator) may be used for convolution with the image, so as to obtain horizontal and vertical gradients of the image. For the Sobel operator, a horizontal convolution kernel thereof is [[−1,0,1], [−2,0,2], [−1,0,1]], and a vertical convolution kernel is [[−1, −2, −1], [0,0,0], [1,2,1]]. The two convolution kernels convolve with the image to obtain the horizontal gradient Gₓ and the vertical gradient G_{y} of the image.
b. Calculation of gradient intensity G: the gradient intensity G is a square root of a sum of squares of the horizontal and vertical gradients of the image. A specific calculation formula is:

$$G = \sqrt{{G}_{x}^{2} + {G}_{y}^{2}} .$$

The formula may be used to obtain the gradient intensity of each pixel. The greater the gradient intensity, the more intense the color change of the pixel, and the more likely the pixel is to be part of an edge.
c. Calculation of gradient direction θ: the gradient direction θ is an arctangent of the horizontal and vertical gradients of the image. A specific calculation formula is:

$$θ = arctan ( {G}_{y} / {G}_{x} )$$

The formula may be used to obtain the gradient direction θ of each pixel, and the gradient direction may help determine a direction of the edge.

Non-maximum suppression: upon calculation of the gradient intensity and the gradient direction, non-maximum suppression is performed. In the image, the gradient direction is perpendicular to the direction of the edge. In the non-maximum suppression step, each pixel in the image is traversed. For each pixel, two neighboring pixels thereof in the gradient direction are checked. One of the two neighboring pixels is in a positive direction of the gradient direction, and the other is in a negative direction of the gradient direction. The gradient intensity of the current pixel is then compared with the gradient intensities of the two neighboring pixels thereof. If the gradient intensity of the current pixel is not the maximum, the gradient intensity of the current pixel is set to 0. This is because only a pixel with the maximum gradient intensity is a true edge point, while the others are not edge points. This process continues until all pixels in the image are traversed. Upon completion of this process, an image containing only true edge points is obtained. Through this step, it may be ensured that the obtained edge is a line as thin as possible.

Dual-threshold processing: upon non-maximum suppression, dual-threshold processing is performed. This is to determine a true edge and potential edges. In this step, two thresholds are set: a high threshold and a low threshold. In a case where the gradient intensity of a pixel is higher than the high threshold, the pixel is considered as a true edge; in a case where the gradient intensity of a pixel is lower than the low threshold, the pixel is not considered as an edge; and in a case where the gradient intensity of a pixel falls between the two thresholds, neighboring pixels of the pixel are checked, in a case where any neighboring pixel is a true edge, the corresponding pixel is considered as a potential edge, otherwise, the corresponding pixel is not considered as an edge.

Edge connection: this is the final step. This is to obtain a complete edge. In this step, all potential edges are connected to form a complete edge.
4. Shape and size identification: upon obtaining the edge of the wafer, a shape and dimensions of the wafer need to be identified. For a circular wafer, a radius and a center position thereof are found by using Hough circle transform. For each edge point in an image space, a circle is drawn in a parameter space, with a radius being a distance from the edge point to a point in the parameter space, and a center being the point in the parameter space. Thus, each point in the parameter space correspondingly has a circle. If the circles corresponding to a plurality of edge points in the image space intersect in the parameter space, intersecting points are true center positions of the circles.

Further, peaks are searched for: upon obtaining the parameter space, peaks therein are searched for. The peaks represent a shape in the image space. A threshold is set, and then all points in the parameter space greater than the threshold are found as peaks. Each peak represents a circle in the image space.

Further, results are returned: finally, the radii and center positions of all found circles are returned. These circles represent the identified shapes and dimensions.

Further, the results are output: finally, the identification results are output, typically as a data structure containing wafer shape and dimension information for use in a subsequent feature extraction step.

### II. Feature Extraction

Upon identification of the wafer, features thereof are extracted for subsequent processing, which specifically includes the following steps:

### 1. Shape Feature Extraction, Including Roundness, Diameter, and Edge Smoothness of the Wafer:

Roundness: the roundness of a contour is calculated. The roundness may be calculated using circumference and area, with the formula: Roundness=4π× Area/(Circumference)². The closer the roundness is to 1, the closer the shape is to a perfect circle.

Diameter: a diameter of the identified circular wafer is calculated.

Edge smoothness(S): the smoothness of the edge is analyzed to check for any obvious gaps or unevenness. A calculation formula for edge smoothness is:

$$S = \frac{1}{1 + {\sum }_{i = 1}^{N - 1} \vert {θ}_{i + 1} - {θ}_{i} \vert}$$

θᵢ denotes the gradient direction of an i-th edge point. N denotes the total number of edge points. |θᵢ₊₁−θᵢ| denotes an absolute value of a gradient direction difference between adjacent edge points.

$${\sum }_{i = 1}^{N - 1} \vert {θ}_{i + 1} - {θ}_{i} \vert$$

denotes a sum of the absolute values of the gradient direction differences between all adjacent edge points.

### 2. Geometric Feature Extraction:

Area and perimeter: an area and a perimeter of the wafer are calculated to determine whether the dimension of the wafer is within an expected range.

Enclosing rectangle: the minimum enclosing rectangle of the wafer is determined, and a length and a width thereof are recorded.

Minimum enclosing circle: the minimum enclosing circle surrounding the wafer is determined, and a radius and a center thereof are recorded.

### 3. Edge Feature Extraction:

Edge contour features: feature points of the edge contour are extracted, and continuity (C) of the edge is calculated. The continuity C is calculated by evaluating the integrity of the edge. Specifically, the continuity evaluates whether an edge is continuous and whether there are any breaks or interruptions. In image processing, the continuity C is typically calculated by statistically analyzing connectivity of edge points. Connectivity refers to the number of pixels within an 8-neighborhood (or 4-neighborhood) of a pixel in an image that are also edge points. If all neighboring pixels of an edge point are edge points, the edge point may be considered as continuous. Conversely, if there are non-edge points among the neighboring pixels of an edge point, the edge point is considered as discontinuous.

A calculation formula of the continuity C may be expressed as:

$$C = \frac{{C}_{L}}{{C}_{A}}$$

where C_{L} denotes the number of connected edge points, which refers to the number of continuous edge points among all edge points; and C_{A} denotes the total number of edge points, which refers to the number of all edge points in the image.

Edge direction distribution: the direction distribution of the edge points is calculated, a histogram of oriented gradient (HOG) is used to represent direction distribution features of the edge, and HOG uniformity (U) is calculated.

HOG uniformity (U) is obtained by calculating distribution uniformity of the histogram of oriented gradient (HOG). The step of calculating the HOG uniformity is as follows:
counting, based on the horizontal gradient Gx and the vertical gradient Gy of each pixel obtained in the wafer identification step, the gradient directions of all pixels to generate the histogram of oriented gradients (HOG). Each bin in the histogram represents a specific gradient direction, and a height of the bin represents the number of pixels in the gradient direction. Then, the uniformity U of the histogram of oriented gradient is calculated. A calculation formula of the uniformity U is an entropy of the histogram, specifically:

$$U = - {\sum }_{i = 1}^{N} p ( i ) log ( p ( i ) )$$

where p(i) denotes a probability of an i-th bin (i.e., a proportion of the number of pixels in the bin to the total number of pixels). Specifically, for each bin of the histogram, a product of the probability p(i) of the bin and a logarithm thereof is calculated, then a negative value is taken, and finally results of all bins are summed. The larger the value, the more uniform the distribution in the gradient direction, and the better the edge quality.

### 4. Comprehensive Feature Fusion:

Feature vector construction: the edge smoothness(S), continuity (C), and HOG uniformity (U) extracted above are fused to construct a comprehensive feature vector Q, which represents the comprehensive edge quality of the wafer. A calculation formula of the comprehensive edge quality Q of the wafer is:

$$Q = ω 1 \times S + ω2 \times C + ω 3 \times U$$

where ω1, ω2, and ω3 are weight coefficients.

### 5. Feature Storage and Output:

Feature storage: the extracted features are stored in a database or file for subsequent use. The features may include raw features, feature vectors after dimensionality reduction, feature point coordinates, etc.

Feature output: the features are output to the central processing unit for use in subsequent laser groove profile design and parameter setting steps.

### III. Groove Profile Feature Input

Upon extraction of the wafer features, specifications of a groove profile required to be designed are determined based on a feature extraction result of the wafer and specific application requirements. The groove profile design is created by using computer-aided design software, and input into the central processing unit. Input values include a required grooving depth D and grooving width W, and a shape and dimensions of the groove profile.

### IV. Laser Parameter Setting

This specifically includes:

### 1. Feature Input and Objective Function Definition

Upon wafer identification, feature extraction, and groove profile feature input, relevant wafer features are extracted, including: the diameter of the wafer, the thickness of the wafer, the edge quality of the wafer, and the required grooving depth and width. An objective function is defined with the features as input, and the function evaluates a grooving effect under different laser parameters. The objective function is defined based on the following factors: the grooving depth (D), the grooving width (W), the comprehensive edge quality (Q), and processing time (T). A calculation formula of the objective function is as follows:

$$F = ω 1 \times {( {D}_{t} - {D}_{a} )}^{2} + ω2 \times {( {W}_{t} - {W}_{a} )}^{2} + ω 3 \times Q + ω 4 \times T$$

where Dₜ and Wₜ denote a target grooving depth and width, Dₐ and Wₐ denote an actual grooving depth and width, Q denotes the edge quality, T denotes the processing time, and ω1, ω2, ω3 and ω4 are weight coefficients.

### 2. PSO Algorithm Initialization

Particle swarm setting: a set of particles are initialized, and each particle represents a laser parameter set, including laser power, a frequency, a scanning velocity, and a focal length.

Position and velocity initialization: positions (i.e., a current parameter set) and velocities (i.e., parameter-adjusted velocities) of particles are randomly generated.

### 3. Fitness Evaluation

A fitness value of each particle, i.e., an objective function value, is calculated. For each particle (a laser parameter combination), simulated grooving is performed once using the parameters. A result of the simulated grooving is measured to obtain the actual grooving depth Dₐ, the actual grooving width Wₐ, and the processing time (T). The actual measurement values are substituted into the objective function to calculate a numerical value. The numerical value is the fitness value of the particle. The smaller the fitness value, the better the grooving effect of the laser parameter set.

### 4. Personal Best Position pBest and Global Best Position gBest Update

For each particle, if a current fitness value is superior to a historical best fitness value thereof, a personal best position (pBest) of the particle is updated. If the current fitness value of the particle is superior to a global best fitness value gBest, the global best position (gBest) is updated.

### 5. Velocity and Position Update

Velocity update: a velocity of a particle is updated based on a current velocity, the personal best position pBest, and the global best position gBest of the particle. A velocity update formula is:

$${V}_{i}^{′} = ω \times {V}_{i} + c 1 \times r 1 \times ( {pBest}_{i} - {x}_{i} ) + c 2 \times r 2 \times ( gBest - {x}_{i} )$$

where

$${V}_{i}^{′}$$

denotes the velocity of a particle i after the update, Vᵢ denotes the velocity of a particle i before the update, xᵢ denotes the position of the particle i, pBestᵢ denotes the personal best position of the particle i, gBest denotes the global best position, w denotes an inertia weight, c1 and c2 denote acceleration constants, and r1 and r2 are random numbers between 0 and 1.

Position update: the position of the particle is updated based on the new velocity. An update formula is: xᵢ₊₁=xᵢ+vᵢ, where a new position xᵢ₊₁ equals a current position xᵢ plus the current velocity vᵢ, ensuring that the updated particle position is within a parameter range.

### 6. Iteration Process

The steps of fitness evaluation, pBest and gBest update, and velocity and position update are repeatedly performed until fitness convergence is achieved. The fitness convergence here refers to the fact that the fitness value (i.e., the objective function value) tends to stabilize over multiple iterations and no longer changes significantly. Specifically, fitness convergence means that the global best fitness value (gBest) of the particle swarm changes very little over several consecutive iterations, indicating that the algorithm has found an optimal solution or is close to a global optimal solution.

Fitness convergence is determined in the following ways:
1) fitness change quantity: if a change quantity of the global best fitness value over several consecutive iterations is lower than a set threshold (0.001), fitness convergence is considered to have occurred; and
2) fitness change rate: a change rate of the global best fitness value is calculated, and if the change rate is lower than a set percentage (0.01%), fitness convergence is considered to have occurred.

### 7. Output of Optimal Parameters

Upon completion of iterations, a laser parameter set corresponding to the global best position gBest is output as the optimal laser parameters.

### 8. Experimental Verification

Experiments are conducted by using the optimized laser parameters to verify a grooving effect. Parameters of the optimization algorithm and the objective function are adjusted based on experimental results to further optimize the laser parameters.

### V. Spot Adjustment

Upon setting the laser parameters, the size, shape, and energy distribution of the spot need to be adjusted. A spot pattern is identified and adjusted by using a neural network algorithm. The operation specifically includes the following steps:

### 1. Data Acquisition and Preprocessing

Acquisition of an image of a spot: the high-resolution scanning device is used to capture a current image of the laser spot. It is ensured that the image is clear and contains complete information about the spot. The captured color image is converted into a grayscale image, so that subsequent processing is simplified. Noise is removed from the image through Gaussian filtering, so that the image is smoothed, and details of the spot are retained.

### 2. Feature Extraction

a. Edge detection: the edge of the spot is extracted by using the edge detection algorithm Canny. The operation specifically includes:

Gradient calculation: the gradient intensity and the gradient direction of each pixel in the image are calculated to find potential edges. The horizontal gradient (Gₓ) and the vertical gradient (G_{y}) of the image are calculated by using the Sobel operator.

Non-maximum suppression: the edge is refined to be a line as thin as possible. Each pixel is traversed, and neighboring pixels thereof in the gradient direction are checked. If the gradient intensity of the current pixel is not the maximum among the neighboring pixels thereof, the gradient intensity of the current pixel is set to 0.

Dual-threshold processing: strong edges, weak edges, and non-edges are distinguished. Specifically, a high threshold and a low threshold are set. Pixels with gradient intensities greater than the high threshold are considered as true edges. Pixels with gradient intensities lower than the low threshold are ignored. Pixels with gradient intensities between the two thresholds are retained as weak edges if the pixels are connected to true edges.

Edge connection: weak edges and strong edges are connected to form complete edges. Each pixel in the image is traversed, and weak edges are connected to strong edges to form a continuous edge line.
b. Energy distribution analysis: energy distribution in a center and surrounding areas of the spot is understood through grayscale value calculation. The operation specifically includes:
calculation of a grayscale value of the center of the spot, i.e., an average of pixel grayscale values of the center region of the spot; calculation of an average grayscale value within a radius of the spot, i.e., an average of grayscale values of all pixels within the radius of the spot; and
grayscale gradient analysis: used to analyze energy changes from the center to the edge of the spot. The grayscale gradient changes from the center to the edge of the spot are calculated. Radial grayscale changes are analyzed to understand the uniformity of energy distribution.
c. Feature calculation: basic shape features of the spot are extracted through geometric feature extraction. The operation includes the following steps:
extracting a size of the spot: a boundary of the spot is found based on an edge detection result; calculating an area of the spot (the total number of pixels within the boundary) to understand the coverage of the spot;
extracting a shape of the spot: a perimeter of the spot is calculated, boundary points obtained from edge detection are traversed, and a total distance between the boundary points is calculated; calculating a shape factor (compactness):

$$C = \frac{4 π \times A}{{P}^{2}}$$

where C denotes the compactness, A denotes the area of the shape, and P denotes the perimeter of the shape;
extracting a center position of the spot: a boundary point set of the spot is found based on the edge detection result; and calculating a center-of-mass (center) position of the spot using the following formula:

$$( {x}_{c} , {y}_{c} ) = ( \frac{{\sum }_{i = 1}^{N} {x}_{i}}{N} , \frac{{\sum }_{i = 1}^{N} {y}_{i}}{N} )$$

where N denotes the number of boundary points, and (xᵢ, yᵢ) denotes coordinates of an i-th boundary point.
d. Energy distribution feature calculation: energy distribution features of the spot are extracted.

Center intensity calculation: pixels around the center of mass of the spot (with the center of mass as the center, pixels within a certain radius are selected) are extracted.

An average of the grayscale values of the pixels is calculated as a center intensity of the spot.

Calculation of an average intensity within the radius: based on the shape of the spot, different regions (e.g., equidistant annular regions along major and minor axes of an elliptical shape) are selected.

An average of the grayscale values of all pixels within each region is calculated as the average intensity of the region.

Radial intensity variation: based on the shape of the spot, grayscale values are extracted from the center of mass outward in different directions (e.g., along the major and minor axes) at a certain step size. An average grayscale value within each radius range is calculated, and a radial grayscale value variation curve is plotted. A change trend of the curve is analyzed to understand the uniformity of energy distribution. For example, if the grayscale value decreases gradually from the center to the edge, it indicates that energy is concentrated in a central region.

### 3. Spot Adjustment

a. Spot pattern prediction: a spot pattern is predicted by using a trained convolutional neural network (CNN) model based on the current spot image, and a corresponding adjustment strategy is generated. The operation includes the following steps:

Image input: the currently acquired spot image is input into the trained CNN model.

Pattern prediction: the model processes the image and outputs a prediction result for the spot pattern and the adjustment strategy. The prediction result includes the parameters of the size, shape, and energy distribution of the spot.
b. Adjustment strategy generation: specific spot adjustment parameters are generated based on the prediction result of the CNN model, so as to optimize spot characteristics. The operation includes the following steps:
analyzing the prediction result: the specific spot adjustment parameters are extracted from the output of the CNN model, including spot power, a focal length, a scanning velocity, etc.; and
generating the adjustment parameters: the specific spot adjustment parameters are generated based on the prediction result and a preset adjustment strategy.

Spot power: output power of a laser unit is adjusted to control energy of the spot.

Focal length: a focal length of the laser unit is adjusted to change the size of the spot.

Scanning velocity: a scanning velocity of the laser unit is adjusted to influence the shape and energy distribution of the spot.
c. Actual spot adjustment: the generated adjustment strategy is applied to a laser device by the central processing unit, so as to actually adjust the spot characteristics. The operation includes the following steps:
control system: the generated spot adjustment parameters are transmitted to the laser device by a laser control system (the central processing unit);
parameter application: the power, focal length, scanning velocity and other parameters of the laser unit are adjusted to change the size, shape, and energy distribution of the spot; and
spot adjustment: the adjustment strategy is actually executed to ensure that the spot characteristics meet expectations.
d. Adjustment effect verification: whether the adjusted spot meets expected requirements is verified, and necessary adjustments and optimizations are performed. The operation includes the following steps:
(1) Acquisition of an adjusted spot image: upon adjustment of the spot, an image acquisition system is used to obtain a new spot image.
(2) Data acquisition and preprocessing:
grayscale conversion: the acquired color image is converted into a grayscale image for easier processing; and
noise reduction: noise is removed from the image by using filtering technologies to obtain a clear spot image.
(3) Extraction of new spot features: the size, shape, and energy distribution features of the adjusted spot are extracted by using an edge detection method.
(4) Adjustment effect evaluation: new spot features are compared with expected features to evaluate whether the adjustment effect meets requirements.

Geometric feature evaluation: geometric features such as the size, shape, and center position of the spot are compared.

Energy distribution evaluation: energy distribution features such as a central intensity, average intensity within the radius, and radial intensity variation of the spot are compared.
(5) Optimization and adjustment:

If the adjustment effect is unsatisfactory, the laser parameters and a spatial light modulator are adjusted based on an evaluation result for another spot adjustment.

The processes of prediction, adjustment strategy generation, and actual adjustment are repeatedly performed until the spot characteristics meet the expected requirements.

Through the above detailed steps, precise spot adjustment can be achieved, it is ensured that the laser device can output spot characteristics that meet the requirements under different conditions, and the quality and efficiency of laser grooving are improved.
4. A training process for the convolutional neural network (CNN) model is as follows:
a. Dataset preparation:

Sample image collection: a large number of sample images containing various spot patterns and corresponding adjustment parameters are collected. These images were captured under different conditions, covering various possible spot shapes and energy distributions.

Dataset structure: the dataset includes images and corresponding adjustment strategies, including spot power, the focal length, the scanning velocity, and other parameters.
b. Data preprocessing:

Image standardization: the images are standardized, including adjusting an image size (uniformly resized to 224×224 pixels) and a grayscale value range (normalized to 0 to 1).

Dataset partitioning: the image data is partitioned into a training set (70%), a validation set (20%), and a test set (10%), and it is ensured that each subset is representative and diverse.
c. CNN model Design:
Model structure:

Convolution layer: used to extract low-level and high-level features of an image. The size and number of convolution kernels should be set according to specific requirements.

Pooling layer: used to reduce feature dimensions, commonly using max pooling or average pooling.

Fully connected layer: used for final classification or regression.

Activation function: a ReLU (linear rectification function) activation function is used to enhance the nonlinear capability of the model.

Output layer: an output layer structure is designed based on task requirements, including a linear output layer for regression tasks.
d. Model training:

Loss function selection: a mean squared error loss function is selected. A mean squared error measures a prediction error of the model by calculating an average of a sum of squares of differences between predicted values and actual values. A calculation formula is:

$$MSE = \frac{1}{n} {\sum }_{i = 1}^{n} {( {y}_{i} - )}^{2}$$

where yᵢ denotes the actual value, ŷᵢ denotes the predicted value, and n denotes the number of samples.

Optimization algorithm: an Adam (adaptive moment estimation) optimization algorithm is selected. An Adam optimizer calculates an adaptive learning rate of each parameter to update model weights, with a calculation formula as follows:

$${θ}_{t} = {θ}_{t - 1} - α \frac{\sqrt{+ ϵ}}{}$$

where θₜ denotes a parameter for a t-th iteration, a denotes the learning rate, \hat{m}ₜ denotes a bias correction for first-order moment estimation, \hat{v}ₜ denotes a bias correction for second-order moment estimation, and ∈ is a small constant to prevent division by zero.

### Training Process:

Model training is performed using the training set, including the following steps:
(1) Forward propagation: training set data is input, and subjected to calculations through each layer of the model to obtain the predicted value.
(2) Loss calculation: an error between the predicted value and the true value is calculated by using the mean squared error loss function.
(3) Backward propagation: a gradient of a loss with respect to the model parameters is calculated by a backward propagation algorithm.
(4) Weight update: the model parameters are updated by the Adam optimizer based on the gradient.

### Hyperparameter Adjustment:

Learning rate adjustment: the learning rate is dynamically adjusted based on loss changes of the validation set. Common methods include learning rate decay and learning rate scheduling.

Batch size adjustment: a batch size is adjusted based on hardware resources and model performance to find an optimal training velocity and model stability.

Hyperparameter optimization: hyperparameters of the Adam optimizer are adjusted, such as a first-order moment estimation decay rate (β1) and a second-order moment estimation decay rate (β2).

### Model Testing

Performance evaluation: generalization performance of the model is evaluated by using the test set; and upon completion of model training, forward propagation is performed by using the test set data to calculate the loss, so as to evaluate performance of the model on unseen data.

Metric evaluation: model performance is evaluated by using the following metrics:

Mean squared error (MSE): used to measure an average squared error between the predicted value and the true value of the model. A calculation formula is:

$$MSE = \frac{1}{n} {\sum }_{i = 1}^{n} {( {y}_{i} - )}^{2}$$

Mean absolute error (MAE): used to measure an average absolute error between the predicted value and the true value. A calculation formula is:

$$MAE = \frac{1}{n} {\sum }_{i = 1}^{n} \vert {y}_{i} - \vert$$

Coefficient of determination (R²): used to measure explanatory power of the model prediction. The closer the value is to 1, the better the model performance. A calculation formula is:

$${R}^{2} = 1 - \frac{{\sum }_{i = 1}^{n} {( {y}_{i} - )}^{2}}{{\sum }_{i = 1}^{n} {( {y}_{i} - \overline{y} )}^{2}}$$

where yᵢ denotes the true value, ŷᵢ denotes the predicted value, n denotes the number of samples, and y̅ denotes an average of the true value.

By following the above steps, it can be ensured that the process of training and testing neural network models is complete and scientific, and that the model performs as expected on both training data and unseen data, ensuring reliability in practical applications.

### 6. Grooving and Inspection

The operation specifically includes the following steps:
1. Setting optimized laser parameters and an adjusted spot: optimization parameters of the laser device are set based on the particle swarm optimization algorithm and the spot adjustment step described above. It is ensured that the parameters such as the laser power, the scanning velocity, and the focal length are correctly set. The shape and energy distribution of the adjusted spot reach an optimal state.
2. Performing actual grooving: the laser device is started to perform the grooving operation. Precise grooving is performed according to a preset path and depth to ensure that the grooving process is stable and meets design requirements.
3. Groove profile image acquisition

Image acquisition: the high-resolution scanning device is used to capture an image of the groove profile to acquire a clear groove profile image, and it is ensured that the image covers the entire groove profile region.

Image preprocessing: the acquired groove profile image is converted into a grayscale image, noise is removed from the image through Gaussian filtering, and the details of the groove profile are retained.

Edge detection: the edge of the groove profile is extracted by using the edge detection algorithm Canny.
4. Contour detection and geometric property calculation

Contour detection: a contour of the groove profile is extracted by using a contour detection algorithm, and geometric properties of the groove profile, such as a contour shape, length and width, are analyzed.

Geometric property calculation: the geometric properties of the groove profile, such as a groove width, a groove depth and a groove shape, are calculated. The depth of the groove profile is measured by using a depth map or height map to ensure that the groove depth meets design requirements.
5. Groove profile quality analysis

Edge quality analysis: the quality of the edge of the groove profile is analyzed, and whether the edge is smooth and free of burrs is evaluated.

Shape evaluation: whether the shape of the groove profile meets design requirements and whether there are any deviations or defects are evaluated.
6. Result evaluation and feedback: the shape and depth parameters of the groove profile are compared with preset standards. The quality of the edge of the groove profile is evaluated by using a statistical method to determine whether the edge meets the expected standards. If the groove profile does not meet requirements, deviations and defects are recorded, and causes are analyzed. The laser parameters and the spatial light modulator are adjusted based on an analysis result, parameters such as the laser power, the scanning velocity and the focal length are optimized, and the spot settings are optimized.
7. Re-grooving and inspection: grooving is performed again based on the adjusted parameters, and the process of image acquisition, preprocessing, and groove profile analysis is repeatedly performed to ensure that the adjusted groove profile meets requirements.
8. Multiple adjustments and optimizations: Through multiple adjustments and feedback, the laser parameters and spot settings are gradually optimized. Results and parameters of each adjustment are recorded to document the optimization process. The operations are performed until the groove profile quality meets the expected requirements, which ensures that the grooving process is stable and efficient.

Through the above steps, it is ensured that the groove profile quality meets the expected requirements during the laser grooving process. The laser parameters and spot settings are gradually optimized through the multiple adjustments and feedback, so that a high-quality grooving effect is achieved.

An embodiment of the present application further provides a system for adjusting a groove profile for laser grooving. The system includes: a high-resolution scanning device for scanning a wafer image and acquiring high-resolution image data; a central processing unit for monitoring, analyzing, and processing the acquired image data; a laser device for an actual wafer grooving operation; and a user interface device for providing a human-machine interaction interface for users to set parameters, monitor processes, and check results.

The laser device includes:
a laser unit for emitting a laser beam;
a first reflector provided at a transmitting end of the laser unit and used for changing a direction of laser beams to a beam expander;
the beam expander erected at a reflective end of the first reflector and used for adjusting a size of a spot;
a second reflector provided at a transmitting end of the beam expander and used for changing the direction of the laser beams to a half wave plate;
the half-wave plate provided at a reflective end of the second reflector and used for changing a laser polarization direction;
a spatial light modulator provided at a light-emitting end of the half wave plate and used for adjusting a shape and energy distribution of the spot;
a 4F system provided at a light-emitting end of the spatial light modulator, and composed of two convex lenses for imaging of the spatial light modulator and filtering out impurities in the laser beam;
a third reflector provided at a light-emitting end of the 4F system and used for changing the direction of the laser beams to an objective lens; and
the objective lens provided at a reflective end of the third reflector and used for focusing the laser beams on a product surface to achieve laser grooving in the product surface.

To further illustrate the technical principles and specific implementations of the present disclosure, the following three specific application examples are provided to detail the operational workflow and effects of the system for adjusting the groove profile for laser grooving.
Application Example 1: referring to FIG. 6, this example aims to enhance the intensity of individual grains of the wafer upon cutting by optimizing the groove profile for laser grooving. The laser device is shown in FIG. 1. The specific method includes: inputting specific groove profile features and controlling parameter setting of the laser device by the central processing unit, to ensure that a bottom of the groove profile is flat, with fluctuations controlled within 1 μm.

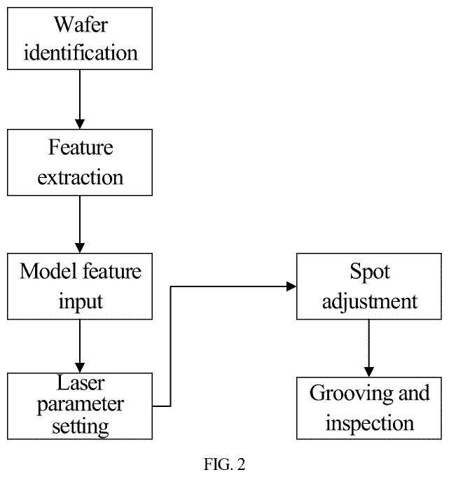

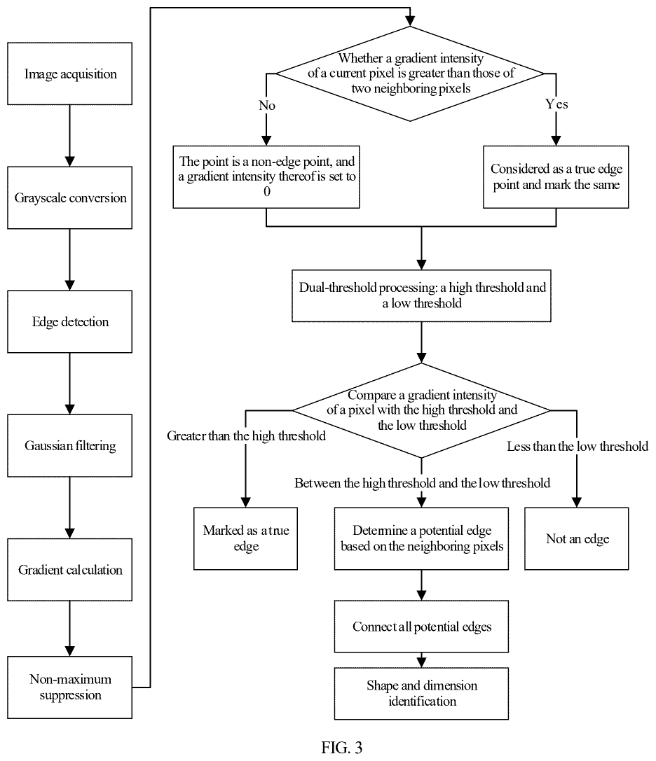

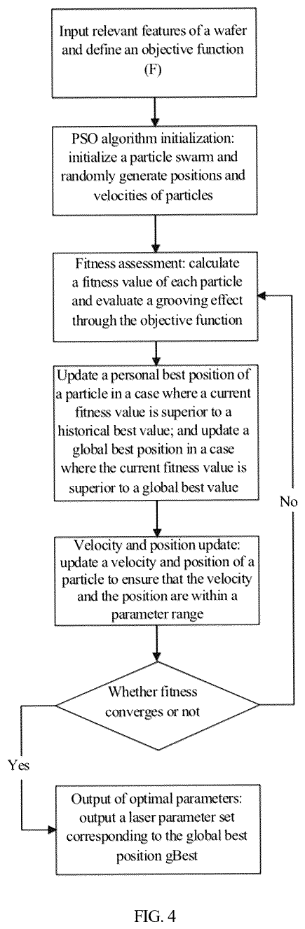

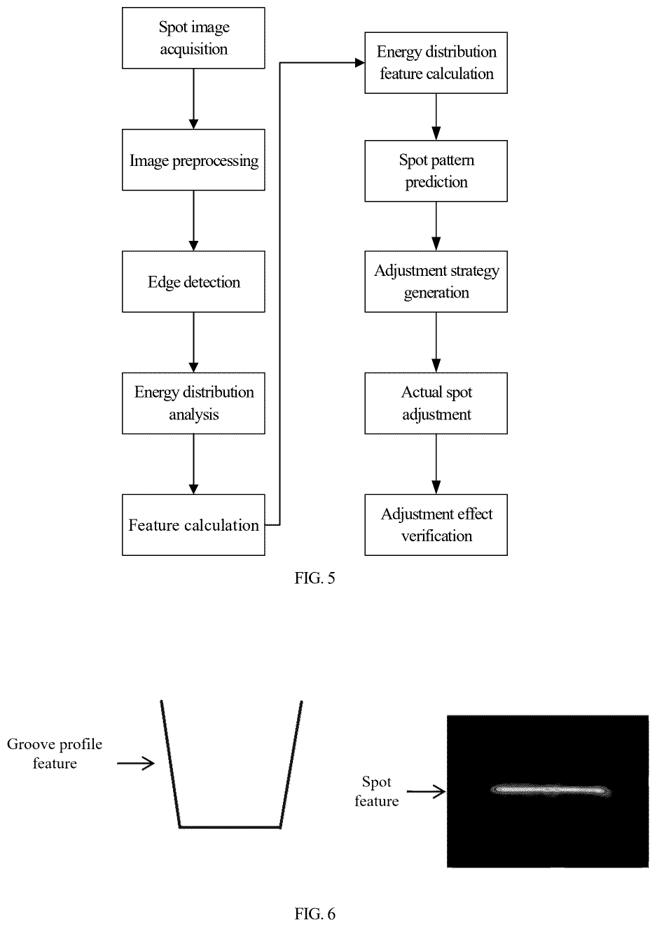

The implementation steps are shown in FIG. 2:
1. Wafer identification: as shown in FIG. 3, a scanning device is used to obtain a wafer image, and the captured color image is converted into a grayscale image. An edge of a wafer is identified by using an edge detection algorithm Canny, and a shape and dimensions of the wafer are identified.
2. Feature extraction: a central processing unit extracts shape features, geometric features, and edge features of the wafer, and calculates edge smoothness S, edge continuity C, and HOG uniformity U of the wafer; and the features are fused to construct a comprehensive feature vector Q.
3. Groove profile feature input: referring to FIG. 6, required groove profile features are input into the central processing unit. The groove profile features include a grooving depth (D), a grooving width (W), and a shape and dimensions of the groove profile. Flatness requirements for a bottom of the groove profile are set, and fluctuations are controlled to be within 1 μm.
4. Laser parameter setting: as shown in FIG. 4, the central processing unit defines an objective function for evaluating a grooving effect under different laser parameters. Laser parameters are optimized by using a particle swarm optimization (PSO) algorithm, and are output.
5. Spot adjustment: as shown in FIG. 5, the central processing unit generates specific spot adjustment parameters by using a convolutional neural network (CNN). The shape features and energy distribution of the spot are detailed in FIG. 6. Here, an energy distribution state of the spot is specifically set to average distribution to ensure that the bottom of the groove profile is flat.

Grooving and inspection: the central processing unit outputs optimized laser power of 5 W, a scanning velocity of 500 mm/s, and a focal length of F40 to the laser device, and performs the grooving operation. The laser device, as shown in FIG. 1, acquires an image of the groove profile upon completion of grooving, contour detection and geometric property calculation are performed on the groove profile, the groove profile quality is analyzed, and result evaluation and feedback are conducted.

Through the above steps, a flat bottom of the groove profile is achieved based on the optimized laser parameters and precise spot adjustment, and fluctuations are controlled to be within 1 μm, so that the intensity of individual grains upon wafer cutting is improved.
Application Example 2: referring to FIG. 7, this example aims to reduce the impact of collisions on grains caused by separation of a knife flywheel machine during subsequent wafer processing by optimizing a groove profile for laser grooving. A specific method includes inputting specific groove profile features, and controlling parameter setting of the laser device through the central processing unit, so as to ensure that two ends of a bottom of the groove profile are deep and a middle is shallow, which effectively blocks heat transfer.

The implementation steps are shown in FIG. 2:
1. Wafer identification: as shown in FIG. 3, a scanning device is used to obtain an image of a wafer, and the captured color image is converted into a grayscale image. An edge of the wafer is identified by using an edge detection algorithm Canny, and a shape and dimensions of the wafer are identified.
2. Feature extraction: a central processing unit extracts shape features, geometric features, and edge features of the wafer, and calculates edge smoothness S, edge continuity C, and HOG uniformity U of the wafer; and the features are fused to construct a comprehensive feature vector Q.
3. Groove profile feature input: referring to FIG. 7, groove profile features are input into the central processing unit. The groove profile features include a grooving depth (D), a grooving width (W), and a shape and dimensions of the groove profile. The shape of the groove profile is specifically set to be deep at the bottom and shallow in the middle.
4. Laser parameter setting: as shown in FIG. 4, the central processing unit defines an objective function for evaluating a grooving effect under different laser parameters. Laser parameters are optimized by using a particle swarm optimization (PSO) algorithm, and are output.
5. Spot adjustment: as shown in FIG. 5, the central processing unit generates specific spot adjustment parameters by using a convolutional neural network (CNN). The shape features and energy distribution output of the spot are detailed in FIG. 7. Specifically, energy distribution output here is: a left side of the groove profile accounts for 40% of the total energy, a right side for 40% of the total energy, and the middle accounts for 20% of the total energy.

Grooving and inspection: the central processing unit outputs optimized laser power of 5 W, a scanning velocity of 500 mm/s, and a focal length of F40 to the laser device, and performs the grooving operation. The laser device acquires an image of the groove profile upon completion of grooving, contour detection and geometric property calculation are performed on the groove profile, the groove profile quality is analyzed, and result evaluation and feedback are conducted.

Through the above steps, by using the optimized laser parameters and precise spot adjustment, the bottom of the groove profile has a shape that the two ends are deep and the middle is shallow, so that the impact of collisions on the grains caused by separation of the knife flywheel machine during subsequent wafer processing is effectively reduced, and accordingly the processing quality and efficiency are improved.
Application Example 3: referring to FIG. 8, this example aims to optimize the groove profile for laser grooving to make the wafer more prone to cracking after backside cutting processing, thereby enhancing the quality and efficiency of backside processing of the wafer. The laser device is as shown in FIG. 1. The specific method includes inputting specific groove profile features and controlling parameter setting of the laser device by the central processing unit, to ensure that two ends of the bottom of the groove profile are shallow and a middle is deep.

The implementation steps are shown in FIG. 2:
1. Wafer identification: as shown in FIG. 3, a scanning device is used to obtain an image of a wafer, and the captured color image is converted into a grayscale image. An edge of the wafer is identified by using an edge detection algorithm Canny, and a shape and dimensions of the wafer are identified.
2. Feature extraction: a central processing unit extracts shape features, geometric features, and edge features of the wafer, and calculates edge smoothness S, edge continuity C, and HOG uniformity U of the wafer; and the features are fused to construct a comprehensive feature vector Q.
3. Groove profile feature input: referring to FIG. 8, groove profile features are input into the central processing unit. The groove profile features include a grooving depth (D), a grooving width (W), and a shape and dimensions of the groove profile. The shape of the groove profile is specifically set to be shallow at the bottom and deep in the middle.
4. Laser parameter setting: as shown in FIG. 4, the central processing unit defines an objective function for evaluating a grooving effect under different laser parameters. Laser parameters are optimized by using a particle swarm optimization (PSO) algorithm, and are output.
5. Spot adjustment: as shown in FIG. 5, the central processing unit generates specific spot adjustment parameters by using a convolutional neural network (CNN). The shape features and energy distribution output of the spot are detailed in FIG. 8. Specifically, energy distribution output here is: a left side of the groove profile accounts for 25% of the total energy, a right side for 25% of the total energy, and the middle accounts for 50% of the total energy.

Grooving and inspection: the central processing unit outputs optimized laser power of 5 W, a scanning velocity of 500 mm/s, and a focal length of F40 to the laser device, and performs the grooving operation. The laser device acquires an image of the groove profile upon completion of grooving, contour detection and geometric property calculation are performed on the groove profile, the groove profile quality is analyzed, and result evaluation and feedback are conducted.

Through the above steps, by using the optimized laser parameters and precise spot adjustment, the bottom of the groove profile has a shape that the two ends are shallow and the middle is deep, so that making the wafer more prone to cracking after backside cutting processing, thereby enhancing the quality and efficiency of backside processing of the wafer.

While examples of the present disclosure have been shown and described, it may be understood by a person of ordinary skill in the art that various changes, modifications, substitutions and alterations may be made to these examples without departing from the principles and spirit of the present disclosure, the scope of which is defined by the appended claims and their equivalents.

1. A method for adjusting a groove profile for laser grooving, comprising:
a wafer identification step: controlling, by a central processing unit, a scanning device to acquire color wafer images, converting the acquired color wafer images into grayscale images, identifying an edge of a wafer by using an edge detection algorithm Canny, and identifying a shape and dimensions of the wafer;
a feature extraction step: extracting, by the central processing unit, shape features, geometric features, and edge features of the wafer, comprising edge smoothness S, edge continuity C, and histogram of oriented gradients (HOG) uniformity U of the wafer, and constructing a comprehensive feature vector Q by fusing the extracted wafer features;
a groove profile feature input step: determining, based on a feature extraction result of the wafer and specific application requirements, specifications of a groove profile required to be designed, and inputting groove profile features into the central processing unit;
a laser parameter setting step: defining, by the central processing unit based on the extracted wafer features, an objective function for evaluating grooving effects under different laser parameters, optimizing the laser parameters by using a particle swarm optimization (PSO) algorithm, and outputting the optimized laser parameters;
a spot adjustment step: controlling, by the central processing unit, the scanning device to capture a current image of a laser spot and preprocessing the image, extracting edges, basic shape features and energy distribution features of the spot by using the algorithm Canny, and inputting the spot image into a convolutional neural network (CNN) model to generate specific spot adjustment parameters; and
a grooving and inspection step: outputting, to a laser device by the central processing unit, the optimized laser parameters and the generated spot adjustment parameters, comprising laser power, a scanning velocity, and a focal length, performing a grooving operation, acquiring a groove profile image upon completion of grooving, performing contour detection and geometric property calculation on the groove profile based on the groove profile image, analyzing groove profile quality, and performing result evaluation and feedback.

2. The method for adjusting the groove profile for laser grooving according to claim 1, wherein in the wafer identification step, the edge detection algorithm Canny comprises:
Gaussian filtering: performing Gaussian filtering on the image to reduce noise in the image and retain edge information of the image;
gradient calculation: performing a convolution operation on the image by using a Sobel operator, calculating a horizontal gradient Gx and a vertical gradient Gy of the image, and calculating a gradient intensity G and a gradient direction θ of each pixel;
non-maximum suppression: traversing each pixel in the image and checking two neighboring pixels of the pixel in the gradient direction, comparing the gradient intensity of a current pixel with the gradient intensities of the two neighboring pixels, in a case where the gradient intensity of the current pixel is not the maximum, setting the gradient intensity of the current pixel to 0, and obtaining an image containing true edge points upon traversing the pixels;
dual-threshold processing: setting a high threshold and a low threshold, and in a case where the gradient intensity of a pixel is higher than the high threshold, considering the pixel as a true edge; in a case where the gradient intensity of a pixel is lower than the low threshold, not considering the pixel as an edge; and in a case where the gradient intensity of a pixel falls between the two thresholds, checking neighboring pixels of the pixel, in a case where any neighboring pixel is a true edge, considering the corresponding pixel as a potential edge, otherwise, not considering the corresponding pixel as an edge; and
edge connection: connecting all potential edges to form a complete edge.

3. The method for adjusting the groove profile for laser grooving according to claim 1, wherein in the feature extraction step, a step of calculating the HOG uniformity U comprises: counting, based on the horizontal gradient Gx and the vertical gradient Gy of each pixel obtained in the wafer identification step, gradient directions of all pixels to generate a histogram of oriented gradient (HOG), wherein a calculation formula of the HOG uniformity U is:
$$U = - {\sum }_{i = 1}^{N} p ( i ) log ( p ( i ) )$$
where p(i) denotes a probability of an i-th bin in the HOG, each bin in the HOG represents a specific gradient direction, and a height of the bin represents the number of pixels in the gradient direction; and N denotes data of the bins in the HOG.

4. The method for adjusting the groove profile for laser grooving according to claim 1, wherein in the feature extraction step, a calculation formula of the comprehensive feature vector Q is:
$$Q = ω1 \times S + ω2 \times C + ω3 \times U ,$$
where ω1, ω2, and ω3 are weight coefficients.

5. The method for adjusting the groove profile for laser grooving according to claim 1, wherein in the groove profile feature input step, the groove profile features comprise: a grooving depth D, a grooving width W, and a shape and dimensions of a groove profile.

6. The method for adjusting the groove profile for laser grooving according to claim 1, wherein in the laser parameter setting step, the step of optimizing the laser parameters by using the particle swarm optimization (PSO) algorithm comprises:
PSO algorithm initialization: initializing a particle swarm and randomly generating positions and velocities of particles;
fitness evaluation: calculating a fitness value of each particle and evaluating a grooving effect through the objective function;
personal best position pBest and global best position gBest update: updating a personal best position of a particle in a case where a current fitness value is superior to a historical best value; and updating the global best position in a case where the current fitness value is superior to a global best value;
velocity and position update: updating the velocities and the positions of the particles to ensure that the velocities and the positions are within a parameter range;
an iteration process: repeatedly performing fitness evaluation, pBest and gBest update, and velocity and position update until fitness convergence is achieved; and
output of optimal parameters: outputting a laser parameter set corresponding to the global best position as the optimal parameters.

7. The method for adjusting the groove profile for laser grooving according to claim 1, wherein in the spot adjustment step, the basic shape features of the spot comprise an area, a shape factor, and a center position, and the energy distribution features of the spot comprise a center intensity and an average intensity within a radius.

8. The method for adjusting the groove profile for laser grooving according to claim 1, wherein in the spot adjustment step, a training process of the CNN model comprises:
dataset preparation: collecting sample images containing various spot patterns and corresponding adjustment parameters and corresponding adjustment strategies of the sample images, comprising power, a focal length, and a scanning velocity of the spot;
data preprocessing: standardizing the images in a dataset and partitioning the dataset;
CNN model design: designing the CNN model, wherein the model comprises a convolutional layer, a pooling layer, and a fully connected layer, and defining an activation function and an output layer structure;
model training: training the model by using a training set, and updating model parameters through forward propagation and backward propagation;
hyperparameter adjustment: adjusting hyperparameters during training, comprising a learning rate, a batch size, and hyperparameters of an optimizer; and
model testing: evaluating the performance of the model using a test set, comprising a generalization capability and prediction accuracy of the model, and evaluating the performance of the model based on evaluation metrics, wherein the evaluation metrics comprise a mean squared error (MSE), a mean absolute error (MAE), and an R² coefficient of determination.

9. An adjustment system for implementing the method for adjusting the groove profile for laser grooving according to claim 1, comprising:
a high-resolution scanning device for scanning wafer images and acquiring high-resolution image data;
a central processing unit for monitoring, analyzing, and processing the acquired image data;
a laser device for an actual wafer grooving operation; and
a user interface device for providing a human-computer interaction interface for users to set parameters, monitor processes, and check results.

10. The adjustment system according to claim 9, wherein the laser device comprises: a laser unit, and a light-emitting end of the laser unit is provided with a first reflector;
a reflective end of the first reflector is provided with a beam expander, and the beam expander is used for adjusting a size of a spot; a light-emitting end of the beam expander is provided with a second reflector;
a reflective end of the second reflector is provided with a half wave plate, and the half wave plate is used for changing a laser polarization direction;
a light-emitting end of the half wave plate is provided with a spatial light modulator, and the spatial light modulator is used for adjusting a shape and energy distribution of the spot;
a light-emitting end of the spatial light modulator is provided with an 4F system, and the 4F system comprises two convex lenses for imaging the spatial light modulator and filtering out impurities in laser beams; and
a light-emitting end of the 4F system is provided with a third reflector, a reflective end of the third reflector is provided with an objective lens, and the objective lens is used for focusing laser beams on a product surface to achieve laser grooving in the product surface.
